(19) United States
(12) Patent Application Publication
(10) Pub. No.: US 2020/0258851 A1
(43) Pub. Date: Aug. 13, 2020

(54) ELECTRONIC MODULE

(71) Applicant: SHINDENGEN ELECTRIC MANUFACTURING CO., LTD., Tokyo (JP)

(72) Inventors: Junya YUGUCHI, Hanno-Shi (JP); Kousuke IKEDA, Hanno-Shi (JP); Kenichi SUZUKI, Hanno-Shi (JP)

(73) Assignee: SHINDENGEN ELECTRIC MANUFACTURING CO., LTD., Tokyo (JP)

(21) Appl. No.: 15/763,062

(22) PCT Filed: Feb. 13, 2017
(86) PCT No.: PCT/JP2017/005155

§ 371 Date: Mar. 23, 2018

(51) Int. Cl. H01L 23/64; H01L 23/373; H01L 25/07

(52) U.S. Cl. CPC H01L 23/642; H01L 25/071; H01L 23/3735

(57) ABSTRACT

An electronic module has an insulating substrate 60, a conductor layer 20 provided on the insulating substrate 60, an electronic element 40 provided on the conductor layer 20, and a heat radiation layer 10 provided on the insulating substrate 20 in an opposite side of the electronic element 40. The heat radiation layer 10 has a plurality of heat radiation layer patterns 15 divided in a plane direction.

### TECHNICAL FIELD

The present invention relates to an electronic module.

### BACKGROUND ART

Conventionally, in an electronic module such as a transfer power module, a heat radiation plate (heat radiation layer) made of copper or the like is provided on a back surface of the electronic module to cool embedded electronic elements or the like (for example, refer to JP 2015-211524 A). If the heat radiation layer is provided as described above, a function as a capacitor may be realized by a conductor layer, an insulating substrate, and the heat radiation layer (the capacitor function may be formed). If the capacitor function is formed as described above, noise due to the electronic elements in the electronic module may be discharged to the outside of the electronic module via the heat radiation layer.

### SUMMARY OF INVENTION

### Technical Problem

The present invention has been made in view of the above points and provides an electronic module capable of reducing noise.

### Solution to Problem

An electronic module according to an aspect of the present invention may comprise:

an insulating substrate;

a conductor layer provided on the insulating substrate;

an electronic element provided on the conductor layer; and

a heat radiation layer provided on the insulating substrate in an opposite side of the electronic element,

wherein the heat radiation layer has a plurality of heat radiation layer patterns divided in a plane direction.

In the electronic module according to an aspect of the present invention,

the electronic element may include a switching element.

In the electronic module according to an aspect of the present invention,

the heat radiation layer patterns may include an entire area where the electronic element is disposed when viewed from a side of the heat radiation layer patterns.

In the electronic module according to an aspect of the present invention,

at least a part of the heat radiation layer patterns may entirely cover a plurality of the electronic elements when viewed from the side of the heat radiation layer patterns.

In the electronic module according to an aspect of the present invention,

an insulating substrate may have a first insulating substrate and a second insulating substrate,

the electronic element may have a first electronic element and a second electronic element,

the heat radiation layer may have a first heat radiation layer and a second heat radiation layer,

the first electronic element may be provided on one side of the first insulating substrate,

the first heat radiation layer may be provided on the other side of the first insulating substrate,

the second electronic element may be provided on one side of the first electronic element,

the second insulating substrate may be provided on one side of the second electronic element,

the second heat radiation layer may be provided on one side of the second insulating substrate, and

at least one of the first electronic element and the second electronic element may have a switching element, when the first electronic element has the switching element, the first heat radiation layer may have a plurality of first heat radiation layer patterns divided in a plane direction, and when the second electronic element has the switching element, the second heat radiation layer may have a plurality of second heat radiation layer patterns divided in the plane direction.

In the electronic module according to an aspect of the present invention,

the conductor layer may have a separation part separated from the insulating substrate.

In the electronic module according to an aspect of the present invention,

the electronic element may be not provided on the separation part.

In the electronic module according to an aspect of the present invention,

wherein the separation part may be connected to a ground terminal or a power supply terminal.

In the electronic module according to an aspect of the present invention,

wherein the electronic element may be provided on the separation part.

In the electronic module according to an aspect of the present invention,

an insulating substrate may have a first insulating substrate and a second insulating substrate,

the electronic element may have a first electronic element and a second electronic element,

the first electronic element may be provided on one side of the first insulating substrate,

the second electronic element may be provided on one side of the first electronic element,

the second insulating substrate may be provided on one side of the second electronic element,

at least one of the first electronic element and the second electronic element may have a switching element, when the first electronic element has the switching element, the separation part may have a first separation part separated from the first insulating substrate, and when the second electronic element has the switching element, the separation part may have a second separation part separated from the second insulating substrate.

### Advantageous Effects of Invention

In the present invention, a heat radiation layer has a plurality of heat radiation layer patterns divided in a plane direction. Therefore, an area of the heat radiation layer in an in-plane direction is reduced, so that a capacity (capacity of a capacitor) in a capacitor function formed by the heat radiation layer, a conductor layer, and an insulating substrate can be reduced. As a result, discharged noise can be suppressed.

### BRIEF DESCRIPTION OF DRAWINGS

FIG. 1 is a longitudinal cross-sectional view of an electronic module according to a first embodiment of the present invention.

FIG. 2 is a diagram of the electronic module according to the first embodiment of the present invention when viewed from the side of a bottom surface, in which originally invisible members are shown by broken lines.

FIG. 3(a) is a diagram of an electronic module according to a first modification of the first embodiment of the present invention when viewed from the side of a bottom surface, in which originally invisible members are shown by broken lines. FIG. 3(b) is a diagram of an electronic module according to a second modification of the first embodiment of the present invention when viewed from the side of a bottom surface, in which originally invisible members are shown by broken lines.

FIG. 4 is a longitudinal cross-sectional view of an electronic module according to a second embodiment of the present invention.

FIG. 5 is a longitudinal cross-sectional view of an electronic module according to a first modification of the second embodiment of the present invention.

FIG. 6 is a longitudinal cross-sectional view of an electronic module according to a second modification of the second embodiment of the present invention.

FIG. 7(a) is a longitudinal cross-sectional view of an electronic module according to a third embodiment of the present invention, which is cut along a straight line A-A of FIG. 7(c). FIG. 7(b) is a longitudinal cross-sectional view of the electronic module according to the third embodiment of the present invention, which is cut along a straight line B-B of FIG. 7(c). FIG. 7(c) is a plan view showing an internal configuration of a sealing part of the electronic module according to the third embodiment of the present invention.

FIG. 8 is a longitudinal cross-sectional view of an electronic module according to a first modification of the third embodiment of the present invention, which corresponds to FIG. 7(a).

FIG. 9 is a longitudinal cross-sectional view of an electronic module according to a second modification of the third embodiment of the present invention, which corresponds to FIG. 7(b).

FIG. 10(a) is a longitudinal cross-sectional view of an electronic module according to a fourth embodiment of the present invention, which corresponds to FIG. 7(a). FIG. 10(b) is a longitudinal cross-sectional view of the electronic module according to the fourth embodiment of the present invention, which corresponds to FIG. 7(b).

FIG. 11(a) is a longitudinal cross-sectional view of an electronic module according to a first modification of the fourth embodiment of the present invention, which corresponds to FIG. 10(a). FIG. 11(b) is a longitudinal cross-sectional view of the electronic module according to the first modification of the fourth embodiment of the present invention, which corresponds to FIG. 10(b).

FIG. 12(a) is a longitudinal cross-sectional view of an electronic module according to a second modification of the fourth embodiment of the present invention, which corresponds to FIG. 10(a). FIG. 12(b) is a longitudinal cross-sectional view of the electronic module according to the second modification of the fourth embodiment of the present invention, which corresponds to FIG. 10(b).

FIG. 13 is a longitudinal cross-sectional view of an electronic module according to a third modification of the fourth embodiment of the present invention, which corresponds to FIG. 10(b).

FIG. 14 is a longitudinal cross-sectional view of an electronic module according to a fourth modification of the fourth embodiment of the present invention, which corresponds to FIG. 10(b).

FIG. 15 is a longitudinal cross-sectional view of an electronic module according to a fifth modification of the fourth embodiment of the present invention, which corresponds to FIG. 10(b).

FIG. 16 is a longitudinal cross-sectional view of an electronic module according to a sixth modification of the fourth embodiment of the present invention, which corresponds to FIG. 10(b).

FIG. 17 is a longitudinal cross-sectional view of an electronic module according to a seventh modification of the fourth embodiment of the present invention, which corresponds to FIG. 10(b).

### DESCRIPTION OF EMBODIMENTS

### First Embodiment

### «Configuration»

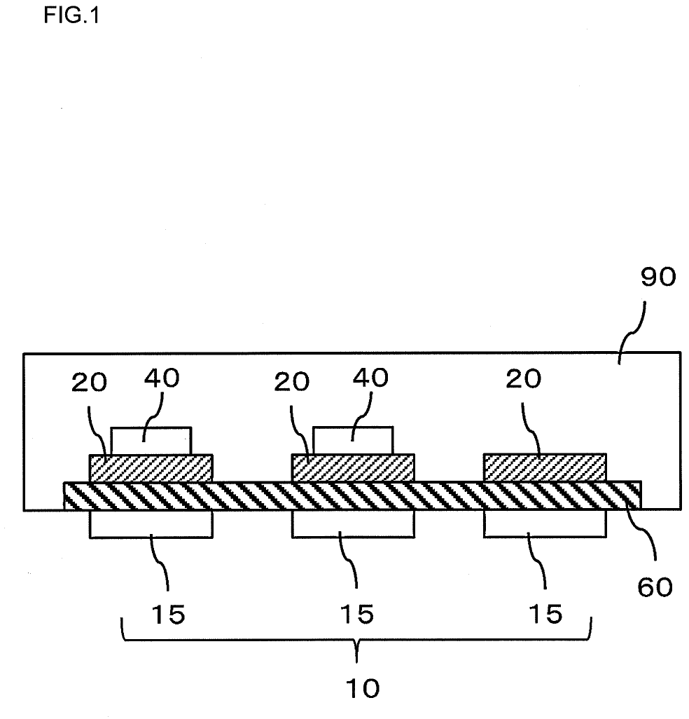

As shown in FIG. 1, an electronic module according to this embodiment may have an insulating substrate 60, conductor layers 20 provided on a front surface of the insulating substrate 60, electronic elements 40 provided on the conductor layers 20, and a heat radiation layer 10 provided on the side (the side opposite to the electronic elements 40) of a back surface of the insulating substrate 60. The heat radiation layer 10 may have a plurality of heat radiation layer patterns 15 divided in a plane direction.

In this embodiment, a semiconductor module can be exemplified as the electronic module and a semiconductor element can be exemplified as the electronic element 40. However, the present invention is not limited thereto and it is not always necessary to use a “semiconductor”.

In addition, the insulating substrate 60, the conductor layer 20, and the electronic element 40 may be covered with a sealing part 90 made of a sealing resin or the like. As shown in FIG. 1, a back surface of the sealing part 90 may be at the same height position as the back surface of the insulating substrate 60. In FIG. 1, an aspect in which the heat radiation layer 10 is provided on the back surface of the insulating substrate 60 and the heat radiation layer 10 protrudes from the back surface of the sealing part 90 is shown. However, the present invention is not limited thereto and the insulating substrate 60 may be buried in the sealing part 90 and the back surface of the heat radiation layer 10 may be at the same height position as the back surface of the sealing part 90.

The electronic element 40 may include a switching element. As the switching element, an FET such as a MOSFET, a bipolar transistor, an IGBT, and the like can be exemplified. Typically, the MOSFET can be exemplified as the switching element.

The conductor layers 20 may be patterned on the insulating substrate 60 to form a circuit. The heat radiation layer 10 may be a metal plate. The conductor layer 20 and the heat radiation layer 10 may be made of copper, for example.

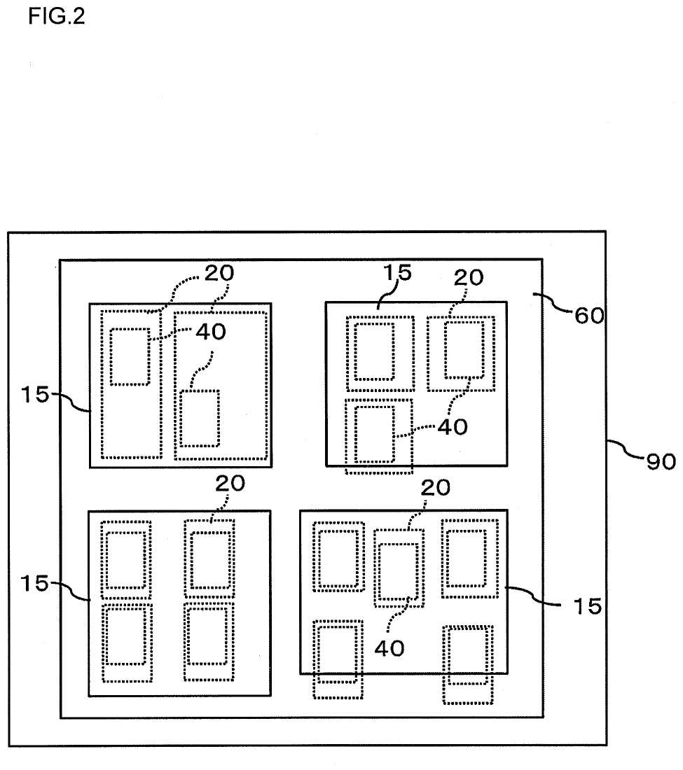

At least a part of the heat radiation layer patterns 15 may entirely cover one or more electronic elements 40 when viewed from the side of the heat radiation layer patterns 15 (when viewed from the lower side in FIG. 1). As an example, the heat radiation layer patterns 15 of the upper left side, the lower left side, and the upper right side in FIG. 2 entirely cover the plurality of electronic elements 40 when viewed from the side of the heat radiation layer patterns 15.

At least a part of the heat radiation layer patterns 15 may be provided to entirely include places where the conductor layers 20 are disposed, when viewed from the side of the heat radiation layer patterns 15. As an example, the heat radiation layer patterns 15 of the upper left side and the lower left side in FIG. 2 entirely cover places where the conductor layers 20 are disposed, when viewed from the side of the heat radiation layer patterns 15.

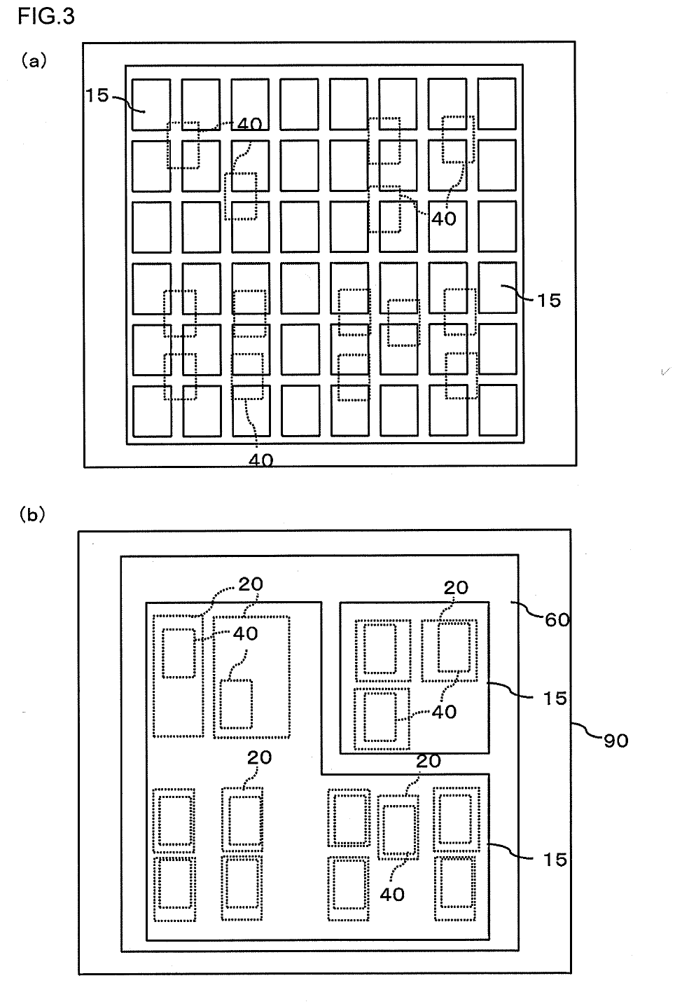

As shown in FIG. 3(a), the heat radiation layer patterns 15 may be provided in a lattice pattern. In addition, as shown in FIG. 3(a), the heat radiation layer patterns 15 may be provided regardless of positions of the electronic elements 40 and the conductor layers 20. That is, the heat radiation layer patterns 15 may be provided in predetermined patterns and the heat radiation layer patterns 15 may be disposed regardless of positions where the heat radiation layer patterns 15 cover the electronic elements 40 or the conductor layers 20 When such an aspect is adopted, it is advantageous in that the heat radiation layer patterns 15 can be easily provided. In FIG. 3(a), the conductor layers 20 are not shown.

In addition, shapes of the heat radiation layer patterns 15 may be different from each other or may be equal to each other. As shown in FIGS. 2 and 3(a), the heat radiation layer patterns 15 may have a rectangular shape or at least one of the plurality of heat radiation layer patterns 15 may have an L shape as shown in FIG. 3(b).

### «Functions/Effects»

Next, functions and effects according to this embodiment having the configuration described above, which are not described, will be described. All configuration described in the “functions/effects” can also be adopted.

When an aspect in which the heat radiation layer 10 has the plurality of heat radiation layer patterns 15 divided in the plane direction is adopted, an area of the heat radiation layer 10 in an in-plane direction is reduced, so that a capacity (capacity of a capacitor) in the capacitor function formed by the heat radiation layer 10, the conductor layer 20, and the insulating substrate 60 can be reduced. As a result, discharged noise can be suppressed. When a capacity C in a parallel plate capacitor is represented as C=εS/d (where “S” is an area of parallel plates, “d” is a distance of the parallel plates, and “E” is permittivity of an insulator existing between the parallel plates), “S” can be reduced by adopting the plurality of heat radiation layer patterns 15.

In particular, when the electronic element 40 has a switching element, noise generated from the switching element is discharged to the outside of the electronic module via the capacitor formed in a pseudo manner by the heat radiation layer 10, the conductor layer 20, and the insulating substrate 60. In this embodiment, the capacity of the capacitor formed in a pseudo manner as described above is reduced, so that the generation of the noise can be suppressed. In the present specification, the term “electronic element 40” (including a “first electronic element 41” and a “second electronic element 42” to be described later) collectively refers to one or more electronic elements. Therefore, “the electronic element 40 has the switching element” means that at least one of the electronic elements 40 is the switching element.

In the case of adopting an aspect in which the heat radiation layer patterns 15 are provided to entirely include the places where the electronic elements 40 are disposed, when viewed from the side of the heat radiation layer patterns 15, it is advantageous in that heat generated by the electronic elements 40 can be easily released by the heat radiation layer patterns 15.

In the case of adopting an aspect in which at least a part of the heat radiation layer patterns 15 entirely covers the plurality of electronic elements 40 when viewed from the side of the heat radiation layer patterns 15 (as an example, in the heat radiation layer patterns 15 of the upper left side, the lower left side, and the upper right side in FIG. 2), it is advantageous in that heat generated from the plurality of electronic elements 40 can be easily released by the heat radiation layer patterns 15.

The heat radiation layer patterns 15 may have the same shapes as the conductor layers 20 and may be provided so that each of the heat radiation layer patterns 15 faces the corresponding conductor layer 20. In the case of adopting such an aspect, it is advantageous in that the heat transmitted through the conductor layers 20 can be efficiently released to the heat radiation layer patterns 15.

In the case of adopting an aspect in which at least a part of the heat radiation layer patterns 15 entirely covers the places where the conductor layers 20 are disposed when viewed from the side of the heat radiation layer patterns 15 (as an example, in the heat radiation layer patterns 15 of the upper left side and the lower left side in FIG. 2), it is advantageous in that the heat transmitted through the conductor layers 20 and generated by the electronic elements 40 can be efficiently released to the heat radiation layer patterns 15.

### Second Embodiment

Next, a second embodiment of the present invention will be described. In the second embodiment, members equal or similar to those in the first embodiment are denoted with the same reference numerals and description thereof is omitted.

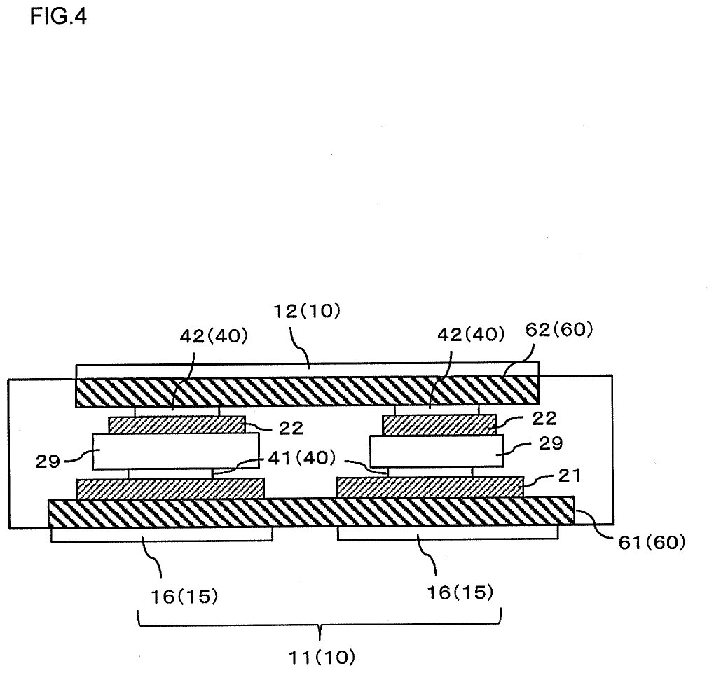

In the second embodiment, electronic elements 40 are stacked and arranged and form a stack structure. More specifically, as shown in FIG. 4, an insulating substrate 60 may have a first insulating substrate 61 and a second insulating substrate 62, the electronic element 40 may have a first electronic element 41 and a second electronic element 42, and a heat radiation layer 10 may have a first heat radiation layer 11 and a second heat radiation layer 12. The first electronic element 41 may be provided on one side (upper side in FIG. 4) of the first insulating substrate 61 and the first heat radiation layer 11 may be provided on the other side (lower side in FIG. 4) of the first insulating substrate 61. The second electronic element 42 may be provided on one side of the first electronic element 41, the second insulating substrate 62 may be provided on one side of the second electronic element 42, and the second heat radiation layer 12 may be provided on one side of the second insulating substrate 62. In addition, a conductor layer 20 may have a first conductor layer 21 and a second conductor layer 22, the first electronic element 41 may be provided on one side of the first conductor layer 21, and the second electronic element 42 may be provided on one side of the second conductor layer 22.

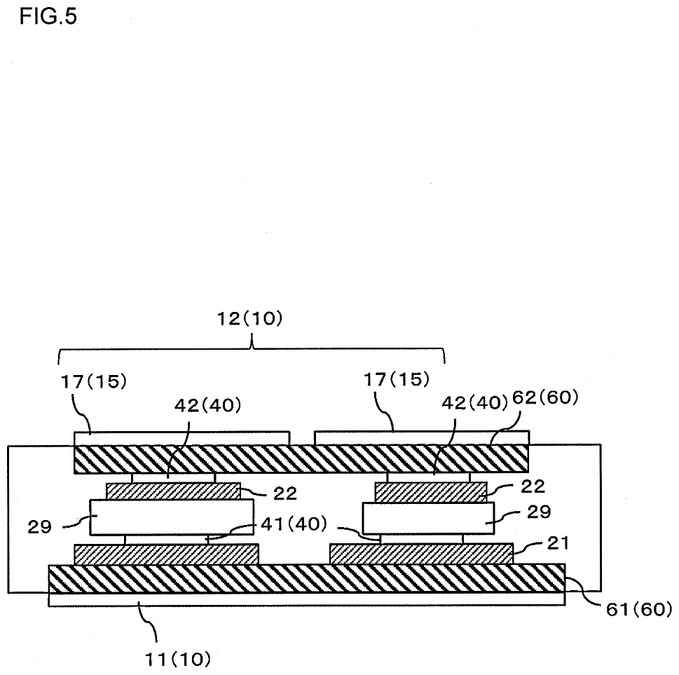

At least one of the first electronic element 41 and the second electronic element 42 may have a switching element. When the first electronic element 41 has the switching element, the first heat radiation layer 11 may have a plurality of first heat radiation layer patterns 16 divided in a plane direction (refer to FIG. 4). In addition, when the second electronic element 42 has the switching element, the second heat radiation layer 12 may have a plurality of second heat radiation layer patterns 17 divided in the plane direction (refer to FIG. 5).

In aspects shown in FIGS. 4 and 5, a conductor post 29 is provided on one side (upper side in FIGS. 4 and 5) of the first electronic element 41 and the second conductor layer 22 is provided on one side (upper side in FIGS. 4 and 5) of the conductor post 29.

As described above, when the electronic element 40 has the switching element, noise tends to increase. Therefore, generation of noise originating from the switching element can be suppressed by adopting an aspect in which the heat radiation layer 10 is divided in the plane direction on at least the side where the switching element is provided to form the plurality of heat radiation layer patterns 15.

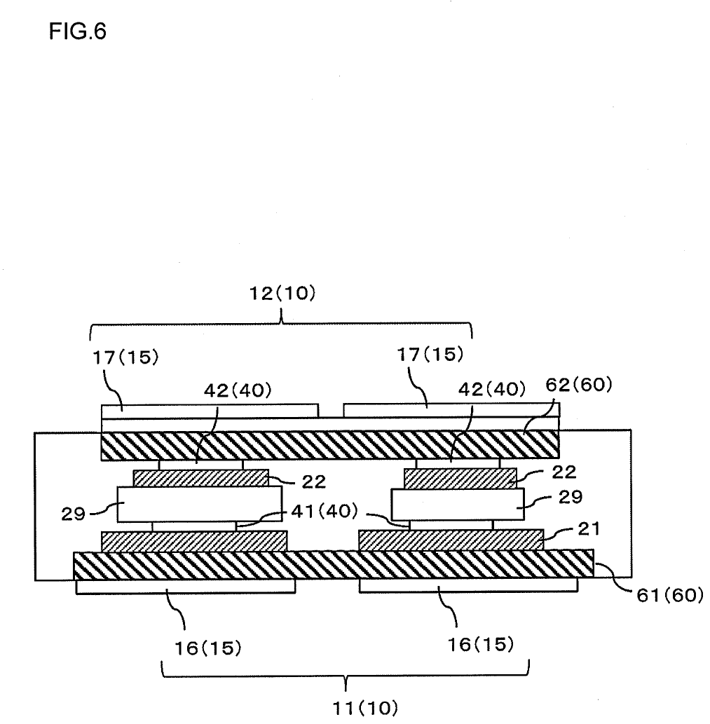

In addition, an aspect in which the heat radiation layer 10 is divided in the plane direction to form the plurality of heat radiation layer patterns 15 may be adopted regardless of whether or not the first electronic element 41 and the second electronic element 42 have the switching element. That is, only the first heat radiation layer 11 may have the plurality of first heat radiation layer patterns 16 divided in the plane direction (refer to FIG. 4), only the second heat radiation layer 12 may have the plurality of second heat radiation layer patterns 17 divided in the plane direction (refer to FIG. 5), or the first heat radiation layer 11 may have the plurality of first heat radiation layer patterns 16 divided in the plane direction and the second heat radiation layer 12 may have the plurality of second heat radiation layer patterns 17 divided in the plane direction (refer to FIG. 6), regardless of whether or not the first electronic element 41 has the switching element or whether or not the second electronic element 42 has the switching element.

In addition, the switching elements may be collected on one side or the other side and the plurality of heat radiation layer patterns 15 may be provided on the side where the switching elements are collected. More specifically, when the first electronic element 41 has the switching element and the second electronic element 42 does not have the switching element, as shown in FIG. 4, the plurality of first heat radiation layer patterns 16 may be provided and one second heat radiation layer 12 may be provided. When the second electronic element 42 has the switching element and the first electronic element 41 does not have the switching element, as shown in FIG. 5, the plurality of second heat radiation layer patterns 17 may be provided and one first heat radiation layer 11 may be provided.

In this embodiment, all configurations (including the modifications) described in the first embodiment can be adopted.

### Third Embodiment

Next, a third embodiment of the present invention will be described. In the third embodiment, members equal or similar to those in the first embodiment or the second embodiment are denoted with the same reference numerals and description thereof is omitted.

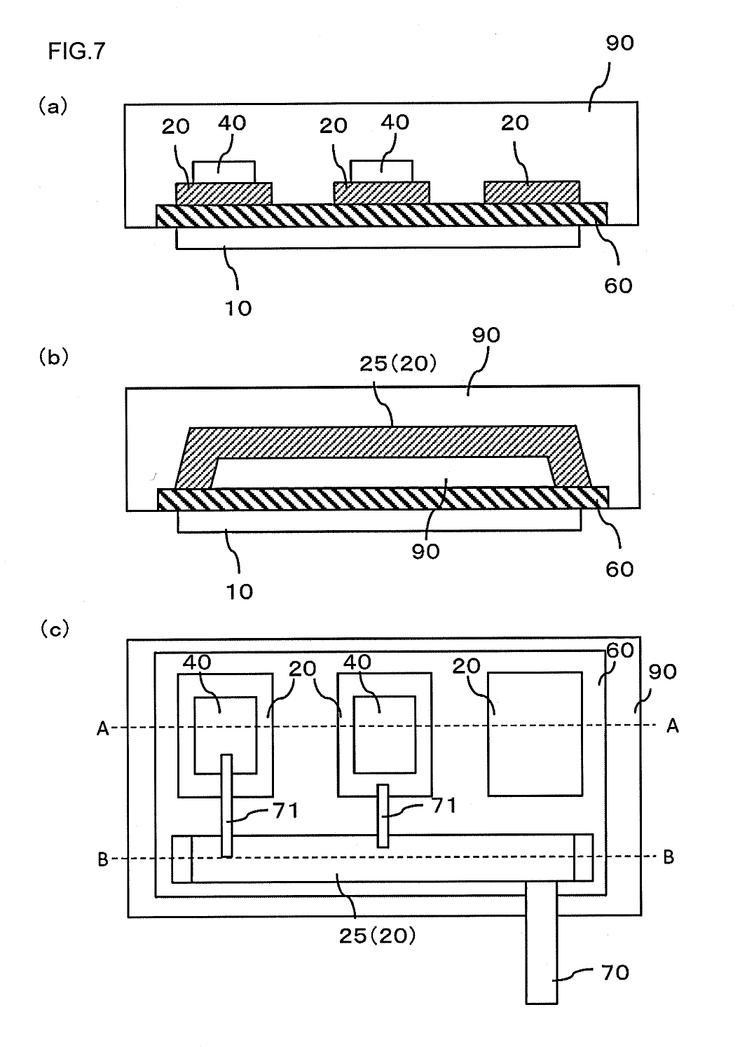

As shown in FIGS. 7(b) and 7(c), in the third embodiment, a conductor layer 20 may have a separation part 25 separated from an insulating substrate 60. By providing the separation part 25, a distance between a heat radiation layer 10 and the separation part 25 can be increased and a capacity (capacity of a capacitor) in a capacitor function formed by the heat radiation layer 10, the conductor layer 20, the insulating substrate 60, and a sealing part 90 can be reduced. As described above, when a capacity C in a parallel plate capacitor is represented as C=εS/d (where “S” is an area of parallel plates, “d” is a distance of the parallel plates, and “r” is permittivity of an insulator existing between the parallel plates), “d” can be increased by adopting the separation part 25. As a result, discharged noise can be suppressed.

An electronic element 40 may not be provided on the separation part 25. By adopting such an aspect, heat generated from the electronic element 40 can be efficiently released by the conductor layer 20 (not the separation part 25) provided on the insulating substrate 60 (refer to FIG. 7(a)) and the capacity in the capacitor function can be reduced by the separation part 25 not provided with the electronic element 40 (refer to FIG. 7(b)).

In addition, all of the conductor layers 20 in which the electronic element 40 is not provided may form the separation part 25. When such an aspect is adopted, all of the conductor layers 20 which rarely contribute to releasing the heat generated from the electronic element 40 can be used as the separation part 25 and the conductor layers can be used to reduce the capacity in the capacitor function.

As shown in FIG. 7(c), when the electronic element 40 is not provided on the separation part 25, the separation part 25 may be connected to a ground terminal or a power supply terminal. A reference numeral 70 shown in FIG. 7(c) denotes the ground terminal or the power supply terminal. When two or more separation parts 25 are provided, the ground terminal may be connected to one separation part 25 and the power supply terminal may be connected to other separation part 25. In addition, the separation part 25 and the electronic element 40 may be connected by a connection part 71 such as a connector and a wire. At this time, the electronic element 40 and the separation part 25 may be directly connected by the connection part 71 (refer to the connection part 71 shown on the left side in FIG. 7(c)) or the electronic element 40 and the separation part 25 may be connected via the conductor layer 20 provided with the electronic element 40 (refer to the connection part 71 shown on the right side in FIG. 7(c)).

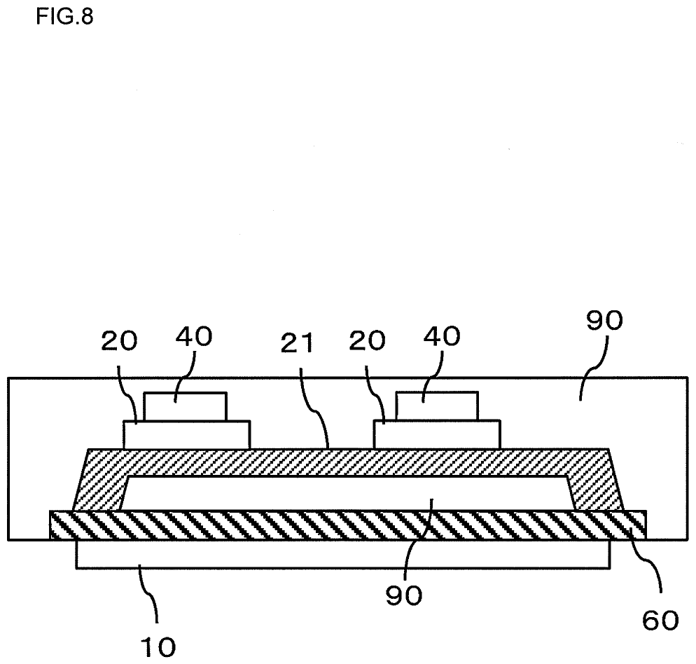

In addition, as shown in FIG. 8, an aspect in which the electronic element 40 is provided on the separation part 25 may be adopted. In this case, although a function of releasing heat generated from the electronic element 40 is lowered, it is advantageous in that the capacity in the capacitor function can be reduced.

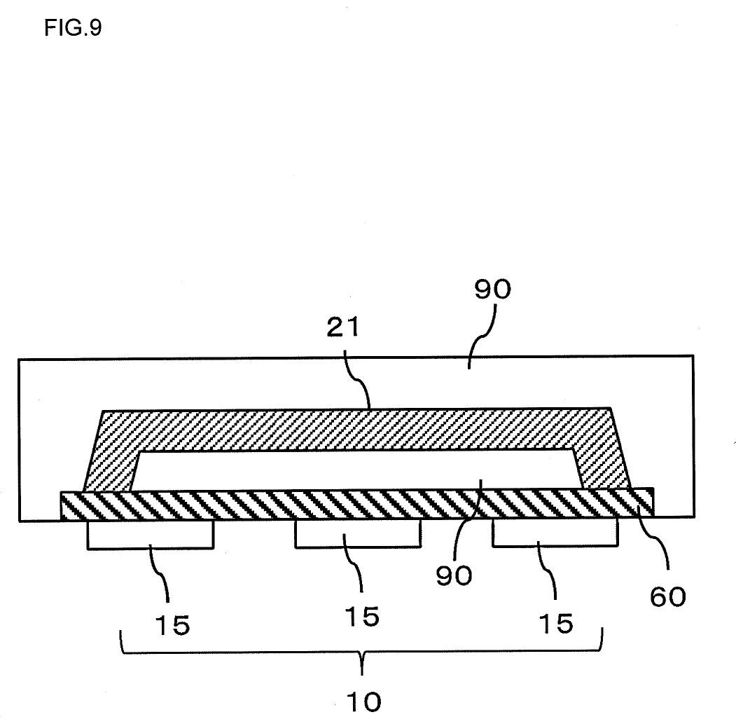

In addition, as shown in FIG. 9, the heat radiation layer 10 may have a plurality of heat radiation layer patterns 15 divided in a plane direction, as shown in the first embodiment and the second embodiment. In this case, an area “S” of the heat radiation layer 10 in an in-plane direction is reduced and the distance “d” between the heat radiation layer 10 and the separation part 25 is increased, so that the capacity (capacity of the capacitor) in the capacitor function formed by the heat radiation layer 10, the conductor layer 20, the insulating substrate 60, and the sealing part 90 can be reduced. Therefore, discharged noise can be suppressed more surely.

In this embodiment, all configurations (including the modifications) described in the first embodiment and the second embodiment can be adopted.

### Fourth Embodiment

Next, a fourth embodiment of the present invention will be described. In the fourth embodiment, members equal or similar to those in the first embodiment, the second embodiment, or the third embodiment are denoted with the same reference numerals and description thereof is omitted.

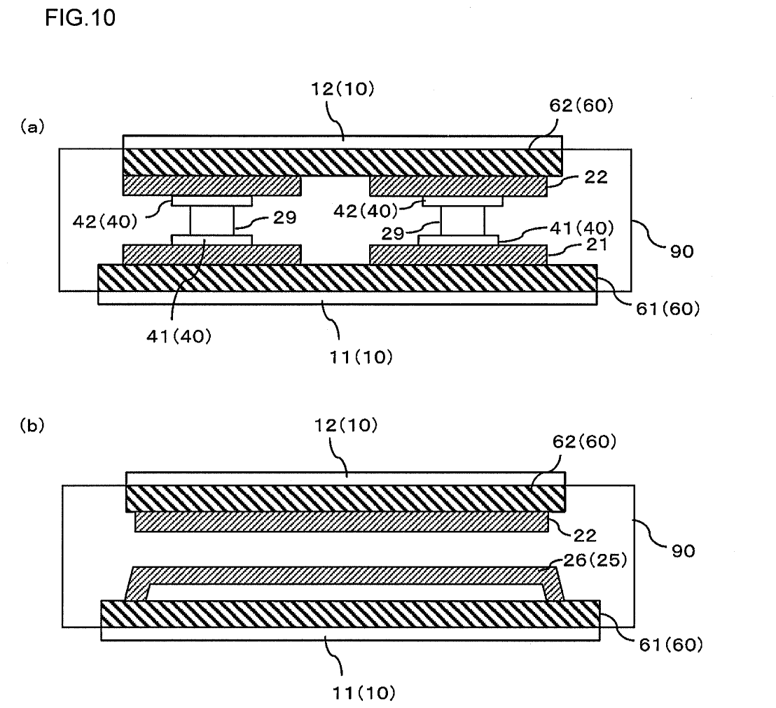

As shown in FIG. 10, in the fourth embodiment, similar to the second embodiment, electronic elements 40 are stacked and arranged and form a stack structure. More specifically, an insulating substrate 60 may have a first insulating substrate 61 and a second insulating substrate 62, the electronic element 40 may have a first electronic element 41 and a second electronic element 42, and a heat radiation layer 10 may have a first heat radiation layer 11 and a second heat radiation layer 12. The first electronic element 41 may be provided on one side (upper side in FIG. 10) of the first insulating substrate 61 and the first heat radiation layer 11 may be provided on the other side (lower side in FIG. 10) of the first insulating substrate 61. The second electronic element 42 may be provided on one side of the first electronic element 41, the second insulating substrate 62 may be provided on one side of the second electronic element 42, and the second heat radiation layer 12 may be provided on one side of the second insulating substrate 62.

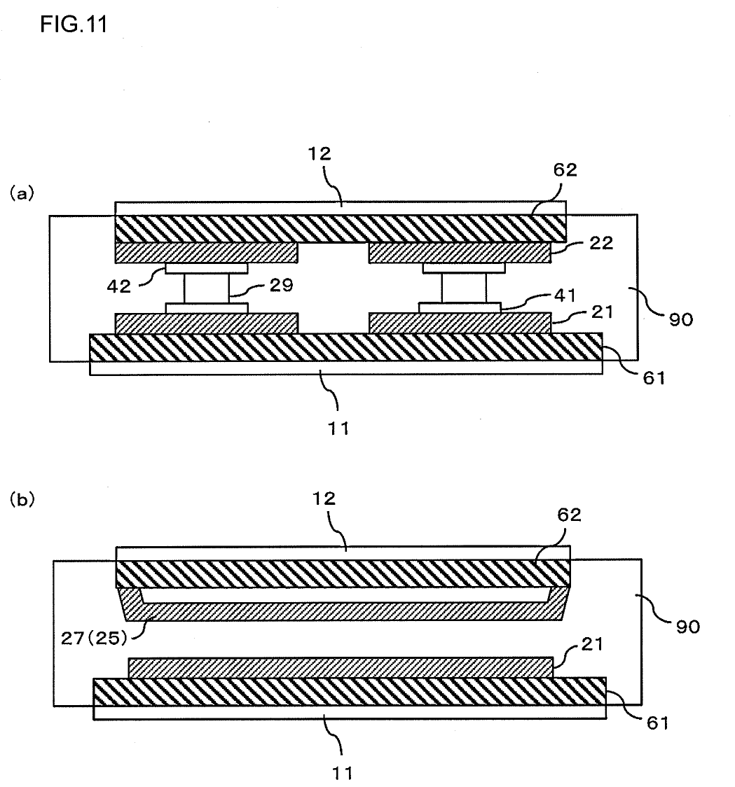

At least one of the first electronic element 41 and the second electronic element 42 may have a switching element. When the first electronic element 41 has the switching element, a separation part 25 may have a first separation part 26 separated from the first insulating substrate 61 (refer to FIG. 10(b)). In addition, when the second electronic element 42 has the switching element, the separation part 25 may have a second separation part 27 separated from the second insulating substrate 62 (refer to FIG. 11(b)).

As described above, when the electronic element 40 has the switching element, noise tends to increase. Therefore, generation of noise originating from the switching element can be suppressed by adopting an aspect in which the separation part 25 is provided on at least the side where the switching element is provided.

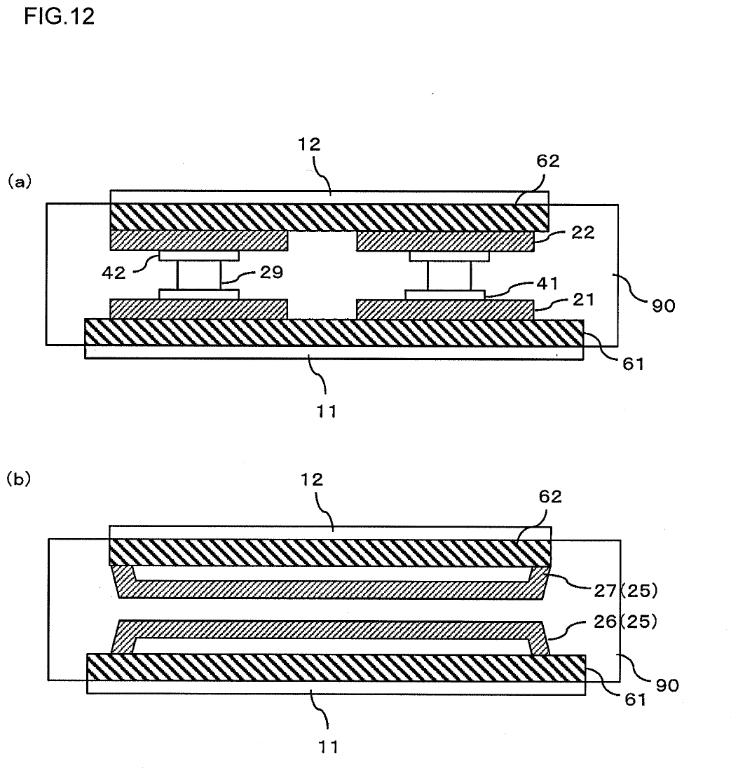

In addition, the separation part 25 may be provided regardless of whether or not the first electronic element 41 and the second electronic element 42 have the switching element. That is, only the first separation part 26 may be provided without providing the second separation part 27 (refer to FIG. 10), only the second separation part 27 may be provided without providing the first separation part 26 (refer to FIG. 11), or both the first separation part 26 and the second separation part 27 may be provided (refer to FIG. 12) regardless of whether or not the first electronic element 41 has the switching element or whether or not the second electronic element 42 has the switching element.

In addition, not only one of the first separation part 26 and the second separation part 27 but also both the first separation part 26 and the second separation part 27 may be provided (refer to FIG. 12). When both the first separation part 26 and the second separation part 27 are provided as described above, a capacity (capacity of a capacitor) in a capacitor function can be further reduced and discharged noise can be suppressed more surely.

In aspects shown in FIGS. 10(a), 11(a), and 12(a), the first electronic element 41 is provided on one side (upper side in FIGS. 10(a), 11(a), and 12(a)) of a first conductor layer 21, a conductor post 29 is provided on one side of the first electronic element 41, the second electronic element 42 is provided on one side of the conductor post 29, and a second conductor layer 22 is provided on one side of the second electronic element 42. The present invention is not limited to these aspects and the conductor post 29, the second conductor layer 22, and the second electronic element 42 may be provided according to aspects shown in FIGS. 4 to 6 in the second embodiment. That is, the first electronic element 41 may be provided on one side of the first conductor layer 21, the conductor post 29 may be provided on one side of the first electronic element 41, the second conductor layer 22 may be provided on one side of the conductor post 29, and the second electronic element 42 may be provided on one side of the second conductor layer 22. In contrast, even in the second embodiment, the conductor post 29, the second conductor layer 22, and the second electronic element 42 may be provided according to the aspects shown in FIGS. 10(a), 11(a), and 12(a).

In addition, the switching elements may be collected on one side or the other side and the separation part 25 may be provided on the side where the switching elements are collected. More specifically, when the first electronic element 41 has the switching element and the second electronic element 42 does not have the switching element, as shown in FIG. 10(b), the first separation part 26 may be provided and the second separation part 27 may not be provided. When the second electronic element 42 has the switching element and the first electronic element 41 does not have the switching element, as shown in FIG. 11(b), the second separation part 27 may be provided and the first separation part 26 may not be provided.

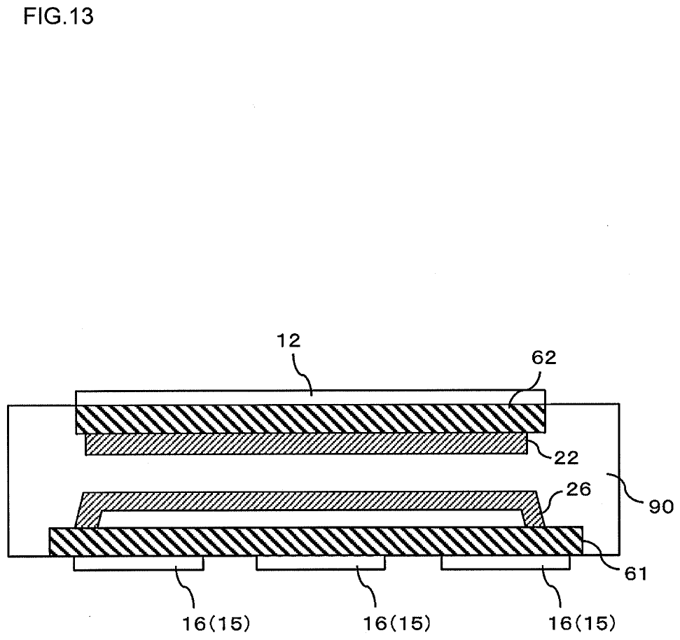

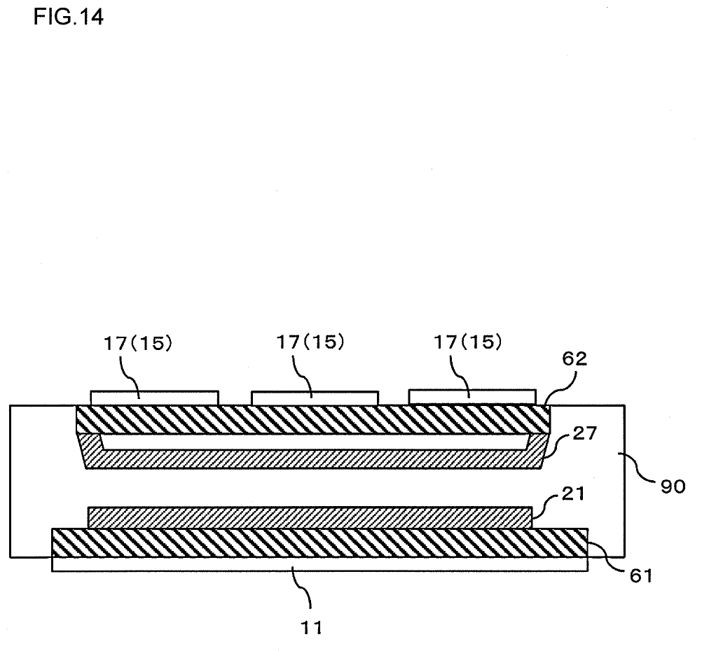

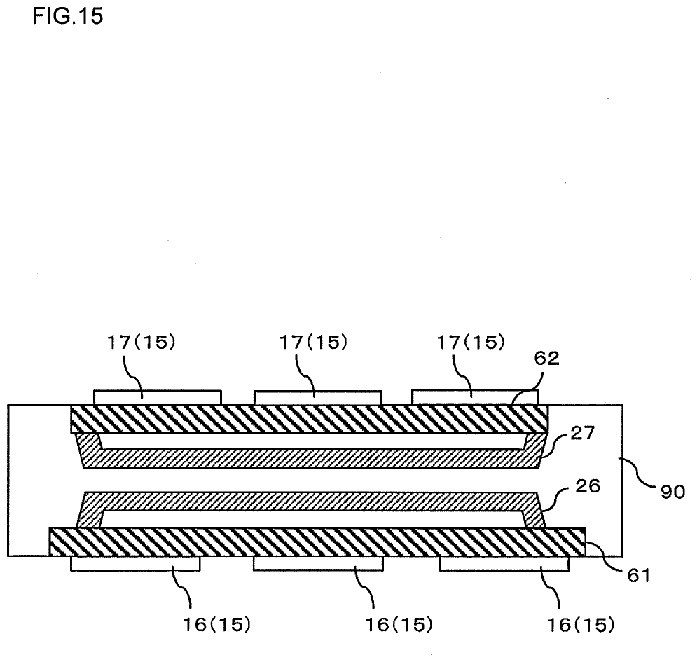

An aspect in which the separation part 25 is provided and an aspect in which the heat radiation layer 10 has a plurality of heat radiation layer patterns 15 may be appropriately combined. For example, the separation part 25 and the plurality of heat radiation layer patterns 15 may be provided on the side having the switching element. In this case, because “S” at C=εS/d can be reduced and “d” can be increased, generation of noise by the switching element can be suppressed more surely. More specifically, (for example, when the first electronic element 41 has the switching element), as shown in FIG. 13, the first separation part 26 and a plurality of first heat radiation layer patterns 16 may be provided. In addition, (for example, when the second electronic element 42 has the switching element), as shown in FIG. 14, the second separation part 27 and a plurality of second heat radiation layer patterns 17 may be provided. In addition, (for example, when the first electronic element 41 and the second electronic element 42 have the switching element), as shown in FIG. 15, the first separation part 26 and the plurality of first heat radiation layer patterns 16 and the second separation part 27 and the plurality of second heat radiation layer patterns 17 may be provided.

In addition, the switching elements may be collected on one side or the other side and the separation part 25 and the plurality of heat radiation layer patterns 15 may be provided on the side where the switching elements are collected. More specifically, when the first electronic element 41 has the switching element and the second electronic element 42 does not have the switching element, as shown in FIG. 13, the first separation part 26 may be provided without providing the second separation part 27 and the plurality of first heat radiation layer patterns 16 and one second heat radiation layer 12 may be provided. When the second electronic element 42 has the switching element and the first electronic element 41 does not have the switching element, as shown in FIG. 14, the second separation part 27 may be provided without providing the first separation part 26 and the plurality of second heat radiation layer patterns 17 and one first heat radiation layer 11 may be provided.

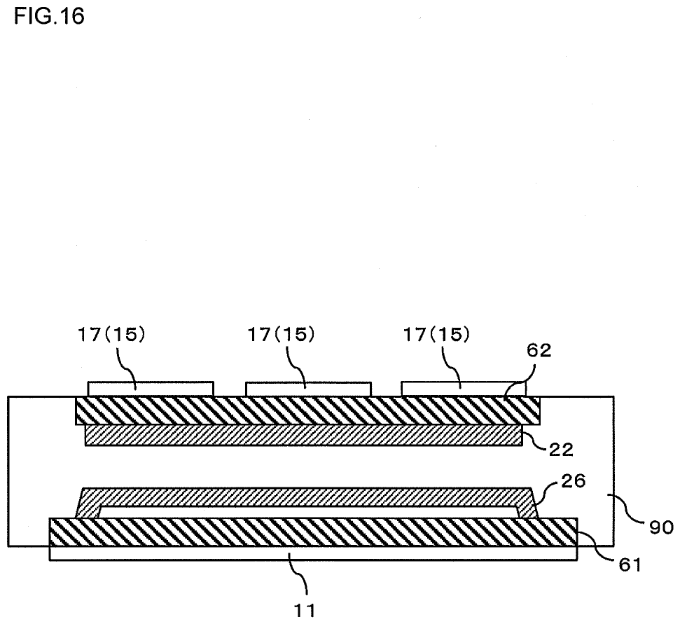

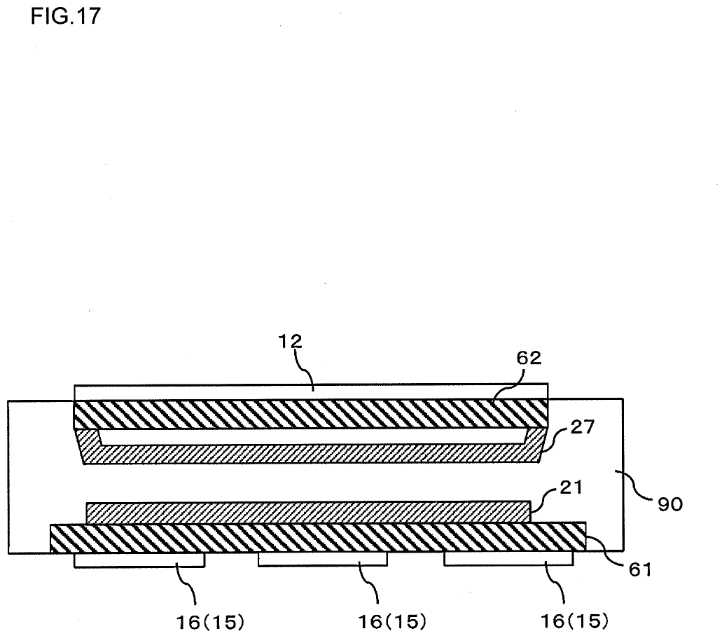

In addition, the separation part 25 and the plurality of heat radiation layer patterns 15 may be provided on the different sides, respectively. For example, according to the magnitude of the noise, the plurality of heat radiation layer patterns 15 may be provided on one side to suppress the noise and the separation part 25 may be provided on the other side to suppress the noise. More specifically, as shown in FIG. 16, an aspect in which the first separation part 26 and the plurality of second heat radiation layer patterns 17 are provided may be adopted. In addition, as shown in FIG. 17, the second separation part 27 and the plurality of first heat radiation layer patterns 16 may be provided.

This embodiment is the same as the first embodiment, the second embodiment, or the third embodiment and can adopt all configurations (including the modifications) described in the first embodiment, the second embodiment, and the third embodiment.

The description of the embodiments, the description of the modifications, and the disclosure of the drawings are merely an example for explaining the invention described in claims and the invention described in the claims is not limited by the description of the embodiments, the description of the modifications, or the disclosure of the drawings. In addition, the description of the claims of the initial application is merely an example and the description of the claims can be appropriately changed on the basis of the description of the specification, the drawings, and the like.

### REFERENCE SIGNS LIST

10 heat radiation layer
11 first heat radiation layer
12 second heat radiation layer
15 heat radiation layer pattern
16 first heat radiation layer pattern
20 conductor layer
25 separation part
26 first separation part
27 second separation part
40 electronic element
41 first electronic element
42 second electronic element
60 insulating substrate
61 first insulating substrate
62 second insulating substrate
70 ground terminal or power supply terminal

1. An electronic module comprising:
an insulating substrate;
a conductor layer provided on the insulating substrate;
an electronic element provided on the conductor layer; and
a heat radiation layer provided on the insulating substrate in an opposite side of the electronic element,
wherein the conductor layer has a separation part separated from the insulating substrate, and
wherein the electronic element is provided on the separation part.

2. The electronic module according to claim 1,
wherein the electronic element includes a switching element.

3. The electronic module according to claim 1,
wherein the heat radiation layer has a plurality of heat radiation layer patterns divided in a plane direction and
wherein the heat radiation layer patterns include an entire area where the electronic element is disposed when viewed from a side of the heat radiation layer patterns.

4. The electronic module according to claim 3,
wherein at least a part of the heat radiation layer patterns entirely covers a plurality of the electronic elements when viewed from the side of the heat radiation layer patterns.

5. The electronic module according to claim 1,
wherein an insulating substrate has a first insulating substrate and a second insulating substrate,
wherein the electronic element has a first electronic element and a second electronic element,
wherein the heat radiation layer has a first heat radiation layer and a second heat radiation layer,
wherein the first electronic element is provided on one side of the first insulating substrate,
wherein the first heat radiation layer is provided on the other side of the first insulating substrate,
wherein the second electronic element is provided on one side of the first electronic element,
wherein the second insulating substrate is provided on one side of the second electronic element,
wherein the second heat radiation layer is provided on one side of the second insulating substrate, and
wherein at least one of the first electronic element and the second electronic element has a switching element, when the first electronic element has the switching element, the first heat radiation layer has a plurality of first heat radiation layer patterns divided in a plane direction, and when the second electronic element has the switching element, the second heat radiation layer has a plurality of second heat radiation layer patterns divided in the plane direction.

6-7. (canceled)

8. The electronic module according to claim 1,
wherein the separation part is connected to a ground terminal or a power supply terminal.

9-10. (canceled)

11. The electronic module according to claim 1,
wherein the insulating substrate has a first insulating substrate and a second insulating substrate,
wherein the electronic element has a first electronic element and a second electronic element,
wherein the first electronic element is provided on one side of the first insulating substrate,
wherein the second electronic element is provided on one side of the first electronic element,
wherein the second insulating substrate is provided on one side of the second electronic element,
wherein at least one of the first electronic element and the second electronic element has a switching element, when the first electronic element has the switching element, the separation part has a first separation part separated from the first insulating substrate, and when the second electronic element has the switching element, the separation part has a second separation part separated from the second insulating substrate.
